(19) United States
(12) Patent Application Publication
(10) Pub. No.: US 2010/0009098 A1
(43) Pub. Date: Jan. 14, 2010

(54) ATMOSPHERIC PRESSURE PLASMA ELECTRODE

(76) Inventors: Hua Bai, Lake Jackson, TX (US); Christopher M. Weikart, Midland, MI (US)

Correspondence Address: The Dow Chemical Company, Intellectual Property Section, P.O. Box 1967, Midland, MI, 48641-1967, US

(21) Appl. No.: 12/441,854

(22) PCT Filed: Sep. 27, 2007
(86) PCT No.: PCT/US2007/021039

§ 371 Date: Mar. 18, 2009

Related U.S. Application Data
(60) Provisional application No. 60/848,940, filed on Oct. 3, 2006.

(51) Int. Cl. C23C 16/453; H05H 1/34

(52) U.S. Cl. 427/569; 118/723 E

(57) ABSTRACT

An improved electrode useful for modifying a substrate using corona discharge dielectric barrier discharge or glow discharge plasma treatment or coating a substrate using plasma enhanced chemical vapor deposition under atmospheric or near atmospheric pressure conditions, the electrode having a body defining a cavity therein, the body having at least one inlet passageway there through in gaseous communication with the cavity so that a gas mixture can be flowed into the cavity by way of the at least one inlet passageway, the electrode having at least one outlet passageway there through in gaseous communication with the cavity so that a gas that is flowed into the cavity can flow out of the cavity by way of the at least one outlet passageway, the at least one outlet passageway being a slot. The improvement is to position a porous body in the cavity sealed to the wall of the cavity adjacent to the outlet passageway so that a gas that is flowed into the cavity will pass through the porous body before flowing through the outlet passageway.

This application claims benefit of U.S. Provisional Application No. 60/848,940, filed Oct. 3, 2006.

### BACKGROUND OF THE INVENTION

The instant invention relates to an improved electrode useful for modifying a substrate using corona or plasma treatment or coating a substrate using plasma enhanced chemical vapor deposition under atmospheric or near atmospheric pressure conditions.

Numerous prior art electrode configurations have been developed for atmospheric or near atmospheric pressure operation. The prior art configurations can be classified into two major types. The first type is intended to be used with a ground electrode positioned on the other side of the substrate from the working electrode. Examples of the first type of electrode are disclosed in WO 2006/049794 and WO 2006/049865. The second type uses a ground electrode position of the same side of the substrate as the working electrode. Examples of the second type of electrode are discussed in WO02/23960, U.S. Pat. No. 6,441,553 and U.S. Pat. No. 7,067,405.

The quality and coating uniformity provided by prior art electrodes is primarily a function of two factors: (a) the gas flow velocity from the electrode onto the substrate to be coated; and (b) the uniformity of the gas flow velocity across the substrate to be coated (as discussed, for example, in USPAP 20050093458). A higher gas flow velocity produces a better quality coating. However, a lower gas flow velocity produces a more uniform coating. Thus, there remains a need for an atmospheric pressure plasma coating electrode that provides both a high gas flow velocity and a uniform gas flow velocity.

### SUMMARY OF THE INVENTION

The instant invention is a solution to the above-mentioned problems. The electrode of the instant invention provides both a high gas flow velocity and a uniform gas flow velocity. More specifically, the instant invention is an improved electrode useful for modifying a substrate using corona discharge or dielectric barrier discharge or glow discharge plasma treatment or coating a substrate using plasma enhanced chemical vapor deposition under atmospheric or near atmospheric pressure conditions, the electrode comprising a body defining a cavity therein, the body having at least one inlet passageway therethrough in gaseous communication with the cavity so that a gas mixture can be flowed into the cavity by way of the at least one inlet passageway, the electrode having at least one outlet passageway therethrough in gaseous communication with the cavity so that a gas that is flowed into the cavity can flow out of the cavity by way of the at least one outlet passageway, the at least one outlet passageway being a slot, wherein the improvement comprises a porous body positioned in and sealed to the wall of the cavity adjacent to the outlet passageway so that a gas that is flowed into the cavity will pass through the porous body before flowing through the outlet passageway.

### BRIEF DESCRIPTION OF THE DRAWINGS

FIG. 1 is a perspective view of an electrode body of a preferred embodiment of the instant invention;

FIG. 2 shows a system for forming a plasma polymerized coating on a substrate using an electrode of the instant invention shown in cross-section; and

FIG. 3 is an end view of another electrode embodiment of the instant invention shown in cross-section.

### DETAILED DESCRIPTION

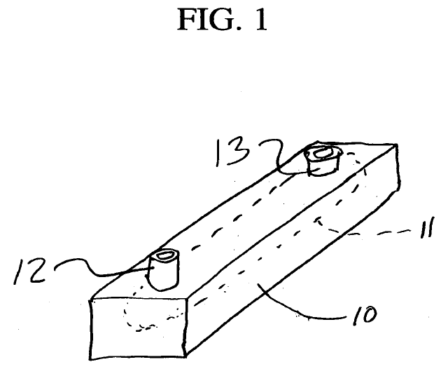

Referring now to FIG. 1, therein is shown a simplified perspective view of an electrode body 10 of a preferred embodiment of the instant invention. The body 10 is made of metal and defines a first cavity 11 therein. The body 10 has a first inlet passageway 12 therein in gaseous communication with the cavity 11. The body 10 has a second inlet passageway 13 therein in gaseous communication with the cavity 11.

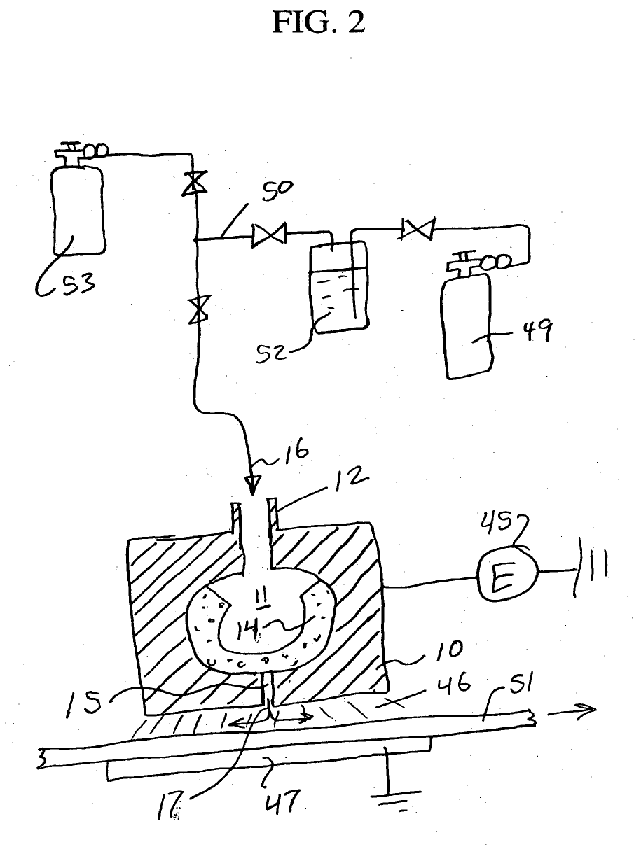

Referring now to FIG. 2, therein is shown a system for forming a plasma polymerized coating on a substrate using the electrode of FIG. 1 shown in cross-section including body 10, inlet passageway 12 and cavity 11. A porous body 14 consisting of a one meter long segment of 12 mm outside diameter, 8 mm inside diameter fritted stainless steel tube (having a porosity of 0.42 and a permeability of 3×10⁸ m²) that is press fit into the chamber 11 in the body 10. The body 10 defines a slot outlet passageway 15 so that a gas 16 that is flowed into the cavity 11 will pass through the porous body 14 before flowing through the outlet passageway 15. The width of the slot 15 is preferably relatively small, for example in the range of from 0.001 to 0.01 inches for a slot height of 6 mm to reduce gas consumption while maintaining a high velocity for the gas 17 passing through the slot 15. The porous body 14 significantly improves the uniformity of gas flow along the length of the slot. The electrode requires sufficient power and frequency via power source 45 to be applied to the electrode to create and maintain, for example and without limitation thereto, a corona discharge 46 in a spacing between the electrode and a substrate 51 positioned on a counter electrode 47. The electrode can be operated, for example and without limitation thereto, between 2 watts and 20,000 watts. The operating frequency can be, for example and without limitation thereto, between 10 Hz and 13.56 MHz. The gap between the electrode and the substrate to be coated can be, for example and without limitation thereto, 1-5 mm. Changing, for example, the gap and the substrate will, of course, require changes to the operating ranges for power and frequency as is well understood in the art.

Referring still to FIG. 2, a mixture of gases 16 including a balance gas 53 and a working gas 50 is flowed into the inlet 12 of the electrode and then out the slot 15 to be plasma polymerized by the corona discharge 46 to form a coating onto the moving substrate 51. As used herein, the term “working gas” refers to a reactive substance, which may or may not be gaseous at standard temperature and pressure, that is capable of polymerizing to form a coating onto the substrate. As used herein, the term “balance gas” is reactive or non-reactive gas that carries the working gas through the electrode and ultimately to the substrate.

Examples of suitable working gases include organosilicon compounds such as silanes, siloxanes, and silazanes generated from the headspace of a contained volatile liquid 52 of such material and carried by a carrier gas 49 from the headspace and merged with balance gas 53 to form the mixture of gases 16. Examples of silanes include dimethoxydimethylsilane, methyltrimethoxysilane, tetramethoxysilane, methyltriethoxysilane, diethoxydimethylsilane, methyltriethoxysilane, triethoxyvinylsilane, tetraethoxysilane, dimethoxymethylphenylsilane, phenyltrimethoxysilane, 3-glycidoxypropyltrimethoxysilane, 3-methacrylpropyltrimethoxysilane, diethoxymethylphenylsilane, tris(2-methoxyethoxy)vinylsilane, phenyltriethoxysilane, and dimethoxydiphenylilane. Examples of siloxanes include tetramethyldisiloxane, hexamethyldisiloxane, octamethyltrisiloxane, and tetraethylorthosilicate. Examples of silazanes include hexamethylsilazanes and tetramethylsilazanes. Siloxanes are preferred working gases, with tetramethyldisiloxane being especially preferred.

The working gas is preferably diluted with a carrier gas 49 such as air or nitrogen before being merged with the balance gas. The v/v concentration of the working gas in the carrier gas is related to the vapor pressure of the working gas, and is preferably not less than 1%, more preferably not less than 5%, and most preferably not less than 10%; and preferably not greater than 50%, more preferably not greater than 30%, and most preferably not greater than 20%.

Examples of suitable balance gases include air, oxygen, nitrogen, helium, and argon, as well as combinations thereof. The flow rate of the balance gas is sufficiently high to drive the plasma polymerizing working gas to the substrate to form a contiguous film, as opposed to a powder. Preferably the flow rate of the balance gas is such that the velocity of the balance gas passing through the slot of at least 1000 feet per minute, more preferably at least 2000 feet per minute, and even more preferably more than 4000 feet per minute (such as 10000 feet per minute or even 20000 feet per minute or more. Control of the relative flow rates of the balance gas and the working gas also contributes to the quality of the coating formed on the substrate. Preferably, the flow rates are adjusted such that v/v ratio of balance gas to working gas is at least 0.002%, more preferably at least 0.02%, and most preferably at least 0.2%; and preferably not greater than 10%, more preferably not greater than 6%, and most preferably not greater than 1%. The actual numeral values for gas injection speed, concentrations, and compositions depends, of course, on the type of coating that is being put down on the substrate as is well understood in the art.

Although it is possible to carry out the process of the present invention by applying a vacuum or partial vacuum in, for example and without limitation thereto, the corona discharge region, (i.e, the region where the corona discharge is formed) the process is preferably carried out so that the corona discharge region is not subject to any vacuum or partial vacuum, that is, carried out at atmospheric or near pressure.

The substrate to be coated or treated by the electrodes of the instant invention is not limited. Examples of substrates include, polyolefins such as polyethylene and polypropylene, polystyrenes, polycarbonates, and polyesters such as polyethylene terephthalate and polybutylene terephthalate.

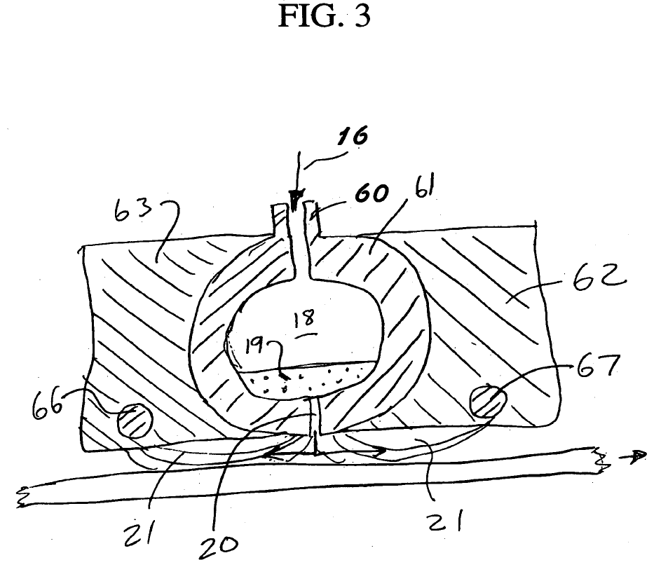

Referring now to FIG. 3, therein is shown an end view of another electrode embodiment of the instant invention in cross-section comprising an aluminum body 61. The body 61 has a gas inlet 60 so that gas can be flowed into a first cavity 18 defined by body 61, through porous body 19 and then flow from slot 20. Dielectric portions 62 and 63 are attached to the body 61 and contain ground rods 66 and 67. When appropriately powered, a plasma 21 generated by the electric field between the body 61 and the ground rods 66 and 67 is formed there between. The porous body 19 is a segment of a one meter long segment of 25 mm outside diameter rod of fritted stainless steel (having a porosity of 0.42 and a permeability of 3×10⁸ m²) that has been sealed to the wall of the chamber 18 with epoxy adhesive.

The porous body used in the instant invention is preferably formed of sintered granules of a solid material such as sintered glass or metal (and especially, sintered granules of stainless steel, available, for example, from SSI-Sintered Specialties, Janesville Wis.). The permeability of the porous body is preferably in the range of from 3×10⁶ m² to 3×10¹⁰ m². The permeability of the porous body is more preferably in the range of from 3×10⁷ m² to 3×10⁹ m². The permeability of the porous body is most preferably in the range of from 1×10⁸ m² to 6×10⁸ m² when the slot height is in the range of from 4-8 mm and when the thickness of the porous body is in the range of from 1.5 to 3 mm.

### CONCLUSION

In conclusion, it should be readily apparent that although the invention has been described above in relation with its preferred embodiments, it should be understood that the instant invention is not limited thereby but is intended to cover all alternatives, modifications and equivalents that are included within the scope of the invention as defined by the following claims.

1. An improved electrode useful for modifying a substrate using corona discharge, dielectric barrier discharge or glow discharge plasma treatment or coating a substrate using plasma enhanced chemical vapor deposition under atmospheric or near atmospheric pressure conditions, the electrode comprising a body defining a cavity therein, the body having at least one inlet passageway therethrough in gaseous communication with the cavity so that a gas mixture can be flowed into the cavity by way of the at least one inlet passageway, the electrode having at least one outlet passageway therethrough in gaseous communication with the cavity so that a gas that is flowed into the cavity can flow out of the cavity by way of the at least one outlet passageway, the at least one outlet passageway being a slot, wherein the improvement comprises a porous body positioned in and sealed to the wall of the cavity adjacent to the outlet passageway so that a gas that is flowed into the cavity will pass through the porous body before flowing through the outlet passageway, wherein the porous body is comprised of sintered granules of a solid material that is a glass material or metal material.

2. The improved electrode of claim 1, wherein the porous body is comprised of sintered granules of a metal material.

3. The improved electrode of any one of claim 1, wherein the permeability of the porous body is in the range of from 3×10⁶ m² to 3×10¹⁰ m².

4. The improved electrode of any one of claim 1, wherein the permeability of the porous body is in the range of from 3×10⁷ m² to 3×10⁹ m².

5. The improved electrode of any one of claim 1, wherein the permeability of the porous body is in the range of from 1×10⁸ m² to 6×10⁸ m².

6. A process of coating a substrate using plasma enhanced chemical vapor deposition under atmospheric or near atmospheric pressure conditions, the process comprising steps of: providing the improved electrode of claim 1; and flowing a gas mixture into the cavity by way of the at least one inlet passageway, through the porous body, and out of the cavity by way of the slot and into an atmospheric pressure or near atmospheric pressure plasma that is in a spacing between the improved electrode and a substrate positioned on a counter electrode to form a plasma enhanced chemical vapor deposition coating on the substrate.
